(19) United States
(12) Patent Application Publication
(10) Pub. No.: US 2026/0029429 A1
(43) Pub. Date: Jan. 29, 2026

(54) TEST PROBE DEVICE

(71) Applicant: Feinmetall Gesellschaft mit beschränkter Haftung, Herrenberg (DE)

(72) Inventors: Arno IHLE, Leonberg (DE); Johannes KIRN, Nagold (DE)

(21) Appl. No.: 18/997,120

(22) PCT Filed: Jul. 21, 2023
(86) PCT No.: PCT/EP2023/070253

§ 371 Date: Jan. 20, 2025

(30) Foreign Application Priority Data
Jul. 21, 2022 (DE) 20 2022 104 119.9

(51) Int. Cl. G01R 1/067

(52) U.S. Cl. CPC G01R 1/06738; G01R 1/06722

(57) ABSTRACT

The invention relates to a test probe device for making electrical contact with an in particular multi-pole contact partner, with a carrier part, which has at least one guide opening, and with at least one test probe, which is longitudinally displaceably mounted in the guide opening, wherein the test probe has a cylindrical housing in which one or more in particular pin-shaped contact elements are arranged, each of which have a contact end for making contact with the contact partner, wherein the housing has a guide portion longitudinally displaceably mounted in the guide opening and a contact portion spaced apart therefrom, and wherein the contact ends are assigned to the contact portion, wherein a spring element is pretensioned between the contact portion and the carrier part and, adjoining the guide portion at the housing, on the side of the carrier part facing away from the spring element, an axial stop is formed, which interacts with the carrier part against the spring force of the spring element, wherein a maximum rotational and/or tilting angle of the test probe is limited relative to the carrier part by the guide opening and the guide portion, for the purpose of which the guide opening and the guide portion in each case have a cross section with at least one straight line, in particular in each case a polygonal cross section, and wherein guide portion and guide opening are formed in such a way that the test probe can tumble in at least one sliding position relative to the carrier part. It is provided that a transfer portion is formed between the guide portion and the axial stop, that the transfer portion has a circular cross section, the diameter of which is at most as large as the smallest diagonal of the cross section of the guide opening on the one hand and smaller than the largest diagonal and larger than the smallest diagonal of the cross section of the guide portion on the other hand, so that the transfer portion, when viewed over its circumference, radially projects beyond the guide portion only in some regions.

### CROSS REFERENCE TO RELATED APPLICATIONS

This application is a national stage entry of International Application No. PCT/EP2023/070253, filed on Jul. 21, 2023, which claims priority to German Patent Application 20 2022 104 119.9, filed on Jul. 21, 2022, which is incorporated herein by reference.

### TECHNICAL FIELD

The invention relates to a test probe device for making electrical contact with an in particular multi-pole contact partner, with a carrier part, which has at least one guide opening, and with at least one test probe, which is longitudinally displaceably mounted in the guide opening, wherein the test probe has a cylindrical housing in which one or more in particular pin-shaped contact elements are arranged so as lie side by side, each of which have a contact end for making contact with the contact partner, wherein the housing has a guide portion longitudinally displaceably mounted in the guide opening and a contact portion spaced apart therefrom, and wherein the contact ends are assigned to the contact portion, wherein a spring element is pretensioned between the contact portion and the carrier part and, adjoining the guide portion at the housing, on the side of the carrier part facing away from the spring element, an axial stop is formed, which interacts with the carrier part against the spring force, wherein a maximum rotational and/or tilting angle of the test probe is limited about its longitudinal axis, in particular its longitudinal central axis or an eccentric longitudinal axis, relative to the carrier part by the guide opening and the guide portion, for the purpose of which the guide opening and the guide portion in each case have a cross section with at least one straight line, in particular in each case a polygonal cross section, and wherein guide portion and guide opening are formed in such a way that the test probe can tumble in at least one sliding position relative to the carrier, thus pivot with its longitudinal axis relative to the longitudinal axis of the carrier part or of the guide opening, respectively.

### BACKGROUND

Test probe devices of the above-mentioned type are already known from the prior art. A generic test probe device is described, for example, in the published patent application DE 20 2019 106 239 U1. By means of an adaptation of the outer cross section of the housing of the test probe to the inner cross section of the carrier part, referred to there as outer housing, it is attained that a maximum tilting angle or angle of rotation of the inner test probe is limited relative to a carrier part. This limitation is thereby changed as a function of a sliding position of the test probe in its longitudinal extension relative to the carrier part. If the test probe device is used for making contact with a contact partner, the test probe device is pushed onto the contact partner with the contact end of the test probe. The spring element is thus elastically deformed and the test probe is displaced relative to the carrier part. In response to this spring deflection of the test probe in the carrier part, the test probe displaces relative to the carrier part in such a way that a region of the guide portion of the test probe, which has a different outer cross section compared to the initial position, which allows for a larger maximum tilting or rotation angle, now lies in the guide opening. In the spring-deflected state, the test probe can thus be twisted farther than in the rebounded state. A similar test probe device is known from the published patent application EP 2 666 022 B1.

### SUMMARY

The present invention is based on the object of creating an improved test probe device, which in particular has a low error rate when carrying out contact-making processes with contact partners, ensures low wear and is formed so as to save installation space.

The object on which the present invention is based is solved by means of a test probe device with the features of claim 1. Said test probe device has the advantage that the twistability of the rotary probe relative to the carrier part is always identical or is limited identically, respectively, independently of the sliding position of the test probe. A maximally permitted angle of rotation of the test probe to the carrier part is thus constant over the entire longitudinal extension or over the entire displacement travel of the test probe, respectively, in the carrier part. It is thus avoided that the test probe is twisted unnecessarily far in response to a contact-making with the contact partner, wherein this twisting would have to be moved back to a corresponding extent again in response to the return of the test probe into the initial position by means of the spring element, with the corresponding consequences for the wear of the test probe device. Should it not be possible to automatically move the test probe back into the region with more strongly limited angle of rotation, for example due to static friction, it can jam and would prevent a further use of the test probe device. Due to the constant maximum angle of rotation of the present invention, it is reliably prevented that problems can arise in response to the transfer of the test probe from the region with increased maximum angle of rotation to reduced maximum angle of rotation. The test probe device is thus less susceptible to errors and is also less fraught with wear. In the case of the present test probe device, the lateral play of the test probe relative to the carrier part is instead reduced in an advantageous manner in the initial position, thus in the rebounded state of the test probe. A wobbling of the test probe relative to the carrier part is understood to be a pivoting or tilting of the test probe or of a central longitudinal axis of the test probe, respectively, relative to a longitudinal axis of the guide opening or of the carrier part, respectively. The compensation of lateral offset between contact partner and carrier part is made possible by means of the tumble movement of the test probe during the contact-making with the contact partner, so that inaccuracies during the positioning of the test probe device relative to the contact partner can be compensated reliably. This is advantageous in the case of test probes, which only have one contact element as well as in the case of test probes, which have several contact elements. In the rebounded state, the axial stop counteracts the force of the spring element and prevents that the test probe can be moved out of the carrier part by means of the spring element. Said axial stop thus defines the maximum rebound travel of the test probe relative to the carrier part. It is attained by means of the embodiment of the test probe device according to the invention that this lateral play is reduced in an advantageous manner in the initial position, thus in the rebounded state of the test probe, so that the test probe reaches a specified initial position with respect to the tumble movement in a simple way. In an advantageous manner, the twistability of the test probe is thereby not influenced, so that a twisting of the test probe already takes place in the first moment of contact with the contact partner, even before a tumble movement is permitted. A safe bringing together of test probe and contact partner is thus ensured at any time. According to the invention, this is attained in that a transfer portion is formed between the guide portion of the test probe and the axial stop. The transfer portion leads from the guide portion to the axial stop. According to the invention, the transfer portion has a circular cross section, the diameter of which is at most as large as the smallest inner width or diagonal of the cross section of the guide opening and smaller than the largest diagonal of the cross section of the guide portion, so that the transfer portion, when viewed over the its circumference, radially projects beyond the guide portion only in some regions. The circular transfer portion is thus larger in some regions than the guide portion, when viewed in the cross section. Due to the fact that in the cross section the guide portion has at least one straight line, which forms a secant to a circular shape, the cross section has a smaller width in the region of the straight line than in an adjacent region, so that the cross section is reduced by means of the secant or straight line. Due to the fact that the cross section of the guide portion has to be smaller than the cross section of the guide opening, and the transfer portion has a diameter, which is at most as large as the smallest inner width or diagonal of the cross section of the guide opening and larger than the smallest width of the cross section of the guide portion, the circular transfer portion lies between the straight line of the cross section of the guide portion and the inner circumference of the cross section of the guide opening, when viewed radially. The transfer portion thus acts as wobbling centering, but without thereby adversely affecting the rotatability or twistability of the test probe relative to the carrier part. Due to the fact that the wobbling centering is assigned to the axial stop, axial stop as well as wobbling centering lie close together and on the side of the carrier part facing away from the spring element. Centering means within the guide opening, on the side of the guide opening facing the spring element, are thus not necessary. The guide opening itself can thus be produced easily, which saves costs and effort. The maximally necessary length of the guide opening furthermore shortens significantly, whereby the test probe device as a whole according to the invention can be produced in a particularly space-saving manner—when viewed in the axial or in the longitudinal displacement direction, respectively.

According to a preferred further development of the invention, the transfer portion has a lead-in slope in at least one region projecting beyond the guide portion. An abrupt transfer from the guide portion to the wobbling limitation is avoided by means of the lead-in slope. In fact, a gentle and low-wear penetration of the transfer portion into the guide opening as well as a centering of the test probe is thus ensured. Depending on the length of the axial extension of the transfer portion, the lead-in slope can be longer or shorter. Compared to the guide portion, the transfer portion is preferably formed to be significantly shorter, wherein the lead-in slope preferably has approximately half of the length of the transfer portion. Due to the circular shape of the transfer portion, the lead-in slope forms a surface of a portion of a circle, which leads from the guide portion to the outer diameter or diameter, respectively, of the transfer portion. For logical reasons, the lead-in slope is formed in the region projecting radially beyond the guide portion and thus leads in particular and preferably from the straight line—when viewed in the cross section of the guide portion—to the transfer portion. A corresponding lead-in slope is preferably assigned to each straight line of the guide portion, which additionally leads to the transfer portion projecting beyond its straight line. When viewed over the longitudinal extension of the guide portion, the respective straight line in the cross section of the guide portion forms a guide surface, which interacts in particular with a guide counter surface of the guide opening, in order to serve as twisting limitation.

The lead-in slope preferably leads from the guide portion so as to rise into the transfer portion, thus with increasing distance from the longitudinal central axis of the test probe, and thus from a guide surface to the larger transfer portion or to the guide portion projecting beyond the guide surface, respectively.

The guide portion preferably has a square cross section. In the cross section, the guide portion is thus characterized by four or at least four straight lines and thus by four guide surfaces, which have the same length and width. It is ensured by means of the square cross section that the profile probe can be inserted into the carrier part or into the guide opening of the carrier part, respectively, in several rotational positions, in each case twisted by 90 degrees. On the one hand, this results in an easy assembly and it is ensured on the other hand that the anti-twist protection or the maximum angle of rotation, respectively, is always the same independently of the assembly position of the test probe.

Alternatively or additionally, the guide opening preferably has a square cross section. A safe interaction with the test probe is ensured at any time hereby. Guide portion as well as guide opening in particular have a square cross section, so that a simple assembly and use of the test probe device is ensured. Due to the square cross section, the guide portion as well as the guide opening in each case have four guide surfaces, which act as anti-twist limitation with one another. The guide surfaces simultaneously act as bearing surfaces for the longitudinal displacement of the test probe relative to the carrier part.

According to a preferred further development of the invention, the guide portion, when viewed in the cross section, has chamfered corners. The guide surfaces thus do not come together directly at an angle of 90 degrees but are connected to one another by means of chamfered corners. The wear of the test probe device is further reduced and the twistability of the test probe is improved by means of the chamfered corners, at least within the scope of the permitted maximum angle of rotation. The straight lines forming the chamfered corners in the cross section are preferably formed to be shorter than the straight lines, which define the respective guide portion.

According to a preferred further development of the invention, the guide opening has rounded corners, when viewed in the cross section. A free space, in which a collision of the guide portion with the carrier part is prevented, is provided to the test probe or the housing of the test probe, respectively, by means of the rounded corners. The chamfered corners of the guide portion can in particular be positioned in an advantageous manner in this region and can be moved in the longitudinal extension as well as in the direction of rotation. Wear and susceptibility to errors are thus reduced. The formation of the cross section of the guide portion as in particular square with rounded corners provides for a maximum of inner installation space with minimal outer dimensions of the test probe.

The maximum angle of rotation or tilting angle, by which the test probe can be twisted about its longitudinal axis, in particular central longitudinal axis or eccentric longitudinal axis, relative to the carrier part, is limited independently of a longitudinal displacement of the test probe in the carrier part. The test probe can thus always be tilted or twisted by the same maximum tilting angle or angle of rotation relative to the carrier part, independently of the sliding position, in which the test probe is located.

According to a preferred further development of the invention, the guide opening has, on its end facing away from the axial stop, a step, which tapers the cross section, wherein the total length of guide portion and transfer portion is larger than the distance of the step from the free end of the guide opening facing the axial stop. It is thus ensured that only the axial stop, which adjoins the transfer portion, is responsible for the unique positioning of the test probe in the rebounded state. A further axial stop, which lies in the guide opening, can thus in particular be dispensed with and is preferably dispensed with. A compact and cost-efficient setup of the test probe device is thus made possible.

According to a preferred further development of the invention, the housing has, in the region of the axial stop, a cross hole with a thread for a holding screw, by means of which connection cables can be fastened in the housing. The connection cables in particular serve the purpose of making electrical contact with the contact element or elements. The connection cables can be locked in the housing by means of the holding screw, so that a strain relief of the connection cables is ensured, which prevents that a tensile force acting on its connection cables has an effect on the contact point between connection cable and contact element. The operational safety of the test probe device is thus optimized.

According to a further advantageous further development of the invention, the contact portion of the housing has, on its free end, at least one lead-in slope for centering the contact partner. It is ensured by means of the lead-in slope that the test probe aligns automatically towards the contact partner in response to making contact with the contact partner. The tumble movement of the test probe relative to the carrier part is effected in particular by means of the lead-in slope. A safe and simple contact-making with the contact partner is ensured hereby.

It is furthermore preferably provided that the contact end of the respective contact element lies completely within the housing, in particular recessed from the free front side of the contact portion. It is in particular ensured therewith that a centering of the test probe to the contact partner already starts before the contact element reaches the contact partner on its own. A safe bringing-together of contact element and contact partner is thus ensured, so that a safe contact-making is ensured even in the case of a large number of test procedures.

According to a preferred further development of the invention, the carrier part has one or more fastening openings spaced apart from the guide opening. For example, fastening screws, by means of which the carrier part can be fastened to a carrier, which optionally carries several carrier parts of this type, can be inserted into the fastening openings.

The carrier part preferably has several guide openings, in which a test probe is assembled or can be assembled in each case. Several test probes can thus be assembled on one carrier part, wherein the guide opening and the test probes are in particular formed as described above. Each test probe can thus be twisted independently of the further test probes of the same test probe device within the scope of the permitted maximum angle of rotation and can be pivoted within the scope of the permissible tumble movement. This results in that contact can simultaneously also be made safely with several contact partners by means of the test probe device.

It is furthermore preferably provided that the carrier part has a width, which is smaller than or equal to the width of the contact portion. The carrier part thus does not laterally project beyond the contact portion or the test probe. It is thus attained that the test probe device as a whole is only as wide as the test probe in the region of the contact portion. A plurality of test probe devices of this type can thus be arranged side by side on a main carrier and the installation space can be utilized in an optimized manner.

According to a preferred further development of the invention, the housing has, between the guide portion and the contact potion, a jacket portion, which surrounds the one or the several contact elements and which is guided radially in the carrier part. The jacket portion of the housing, which extends in particular in the extension of the guide portion, is thus likewise guided radially in the carrier part, whereby the tumble movement of the test probe can be set better. The larger the distance between the guided jacket portion and the transfer portion or the axial stop, respectively, the better the tumble movement can be set.

In order to guide the jacket portion, a bearing ring is preferably present, which is elastically and/or plastically deformable at least in some regions and which is held in a radially tensioned manner at least in some portions between the jacket portion and the carrier part. The bearing ring is thus provided as intermediate bearing between carrier part and jacket portion, and is formed, for example, in an advantages manner in terms of materials, in order to ensure low friction values. Due to the elastic and/or plastic deformability of the bearing ring, a preferably play-free guidance of the jacket portion and thus of the test probe or of the housing, respectively, is ensured in the carrier part, at least in the region, in which the bearing ring acts. The wobbling play and/or rotational play of the test probe is maintained in the region of guide portion so as to be unaffected hereby. It is ensured by means of the elastic deformability that the bearing ring prevents a jamming and thus a locking of the housing in a sliding position. The portion of the guide opening, in which the bearing ring is arranged, is preferably formed with a circular cross section, just like the jacket portion, so that a rotational movement of the test probe relative to the carrier part is not adversely affected in the region of this bearing point. The bearing ring is thereby formed in such a way that it permits an axial displacement of the jacket portion or of the test probe, respectively, relative to the carrier part and acts or is formed as sliding ring in this respect.

The bearing ring particularly preferably has a lead-in slope for the carrier part, which, on the one hand, simplifies the assembly and, on the other hand, provides for the above-mentioned advantageous play compensation during the assembly by means of elastic deformation of the bearing ring itself. For this purpose, the bearing ring is preferably formed conically, so that its outer diameter decreases in the insertion direction into the carrier part. The bearing ring particularly preferably has a bearing ring stop, which limits the maximum penetration depth of the bearing ring into the carrier part. The bearing ring stop is thus formed as axial stop, which directly interacts in particular with the carrier part and has an outer diameter, which is larger than the opening or the portion of the guide opening of the carrier part, in which the bearing ring is inserted into the carrier part for assembly purposes.

The bearing ring preferably has a bearing ring stop, which projects radially outwards and which is held between the spring element on one side and the carrier part on the other side. At one end, the spring element thus does not support itself directly on the carrier part but axially on the bearing ring, which, in turn, supports itself on the carrier part. A pretensioning force, which acts in the direction of the carrier part and which pushes the bearing ring into the guide opening of the carrier part receiving the bearing ring, is thus always applied to the bearing ring by means of the spring element. Due to the preferred elastic deformability of the bearing ring, the latter adapts itself optimally to jacket portion and carrier part, the pretensioning force ensures that the sliding or bearing contact to jacket portion and carrier part is never released, whereby a permanently safe operation is ensured. The deformability of the bearing ring is thereby preferably designed in such a way that the elastic and/or plastic deformation is triggered and maintained by means of the pretensioning force of the spring element. A deformation-or wear-related weakening of the radial tensioning force of the bearing ring is then compensated by the spring element by means of the permanent pushing into the carrier part.

### BRIEF DESCRIPTION OF THE DRAWINGS

The invention will be described in more detail below on the basis of the drawing, in which

FIG. 1 shows an advantageous test probe device in a perspective illustration,

FIG. 2 shows the test probe device in a perspective longitudinal sectional illustration,

FIG. 3 shows a perspective illustration of a part of a housing of the test probe device,

FIG. 4 shows a perspective longitudinal sectional illustration of the part and of a carrier part of the test probe device,

FIG. 5 shows a further perspective longitudinal sectional illustration of the test probe device,

FIG. 6 shows a cross sectional illustration of the test probe device,

FIGS. 7A and B show different assembly options of the test probe device,

FIG. 8 shows an advantageous further development of the test probe device in a perspective illustration and

FIG. 9 shows an enlarged longitudinal sectional illustration of the test probe device

### DESCRIPTION OF THE EMBODIMENTS

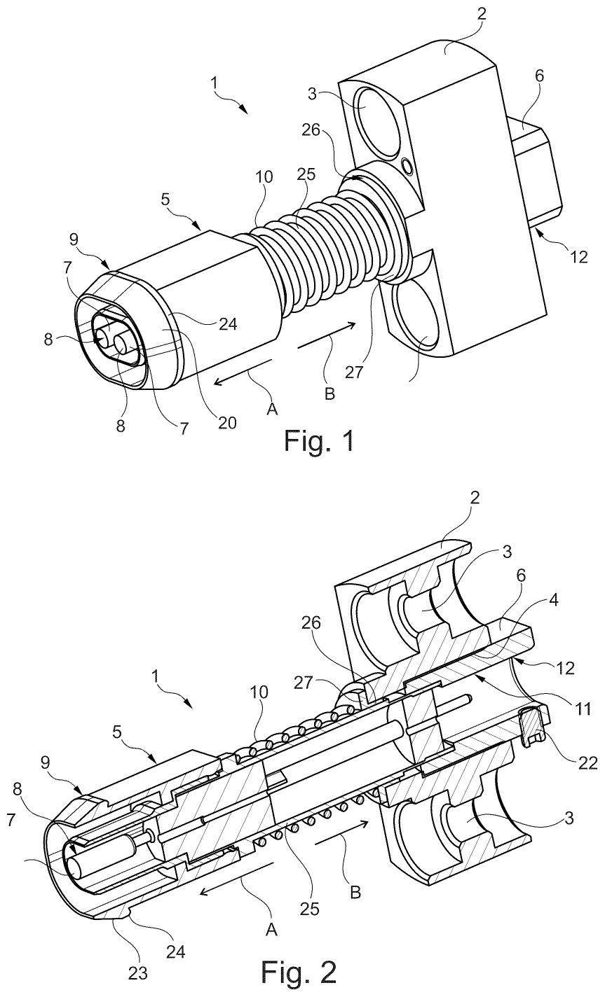

FIG. 1 shows, in a perspective illustration, a test probe device 1, which is formed for making electrical contact with a contact partner. The contact partner is, for example, a printed circuit board or a different type of electrical/electronic test object, which is to be checked with regard to its functionality. Electrical contact with the contact partner can be made by means of the test probe device 1 by means of direct contact, so that, for example, a current can be conducted or a voltage can be electrically applied to the test object by means of the contact partner, in order to test the functionality thereof.

So that a safe contacting process can be carried out, during which in particular position tolerances from contact partner to test probe device I can be compensated, the test probe device 1 described herein provides that it is formed to be rotatable and pivotable in some regions. FIG. 2 shows the test probe device 1 in a perspective longitudinal sectional illustration for this purpose.

The test probe device 1 has a carrier part 2, which has two fastening openings 3, by means of which the carrier part 2 can, for example, be fastened, in particular screwed, to a main carrier. The carrier part 2 has a guide opening 4 between the fastening openings 3. A test probe 5 is longitudinally displaceably mounted in this guide opening 4. The test probe 5 has a multipart housing 6, in which two pin-shaped contact elements 7 are arranged according to the present exemplary embodiment. The contact elements 7 are in particular formed as spring contact probes. According to the present initial example, the contact elements 7 have a contact end 8, which is formed as female contact plug for receiving a male contact plug. The contact ends 8 lie in a contact portion 9 of the test probe 5 or of the housing 6, respectively. The contact end 9 is arranged spaced apart from the carrier part 2. A spring element 10, in the present case a coil spring, which pushes the contact portion 9 away from the carrier part 2, is held in a pre-tensioned manner between the contact end 9 and the carrier part 2. According to the present initial example, the coil spring is arranged coaxially to the housing 6 between the contact portion 9 and the carrier part 2.

The housing 6 of the test probe 5 furthermore has a guide portion 11, which serves the purpose of mounting and guiding of the test probe 5 in the guide opening 4 of the carrier part 2. With respect to the following figures, the guide portion 11 will be discussed in more detail below. An axial stop 12, the outer cross section of which is larger than the cross section of the guide opening 4, adjoins the guide portion 11, so that on the side facing away from the spring element 10, the housing 6 can be pushed all the way to the carrier part 2 with the axial stop 12 until the axial stop 12 strikes the carrier part 2. A further displacement of the test probe 5 by means of the spring element 10 is thus prevented by means of the axial stop 6. The test probe 5 is thus held on the carrier part 2 between spring element 10 and axial stop 12. Due to the multi-part formation of the housing 6, a simple assembly of the test probe 5 is thus ensured on both sides of the carrier part 2, wherein at least the housing part having the guide portion 11 has to be inserted into the carrier part 2 from the side facing away from the spring element.

The coil spring thus pushes the test probe into an initial position according to arrow A, in which the axial stop 12 abuts the carrier part 2. If a contact-making process is carried out, the test probe 5 is pushed onto the contact partner with the contact end 9, whereby the test probe 5 can spring-deflect into the carrier part 2 against the spring force. The spring deflection direction is displayed in FIGS. 1 and 2 by means of an arrow B. During the spring deflection, the guide portion 11 of the housing 6 is pushed out of the guide opening 4 at least in some regions.

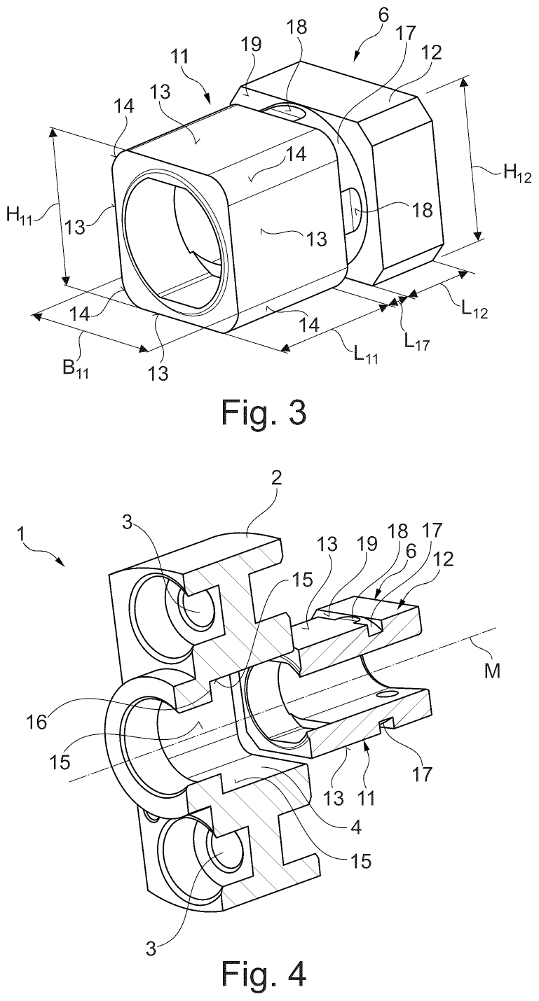

FIG. 3 shows the housing part of the housing 6 having the guide portion 11 in a perspective illustration. The guide portion 11 is formed with a constant cross section, when viewed in the longitudinal extension of the housing 6. The cross section is formed to be square thereby, with four straight lines arranged at a right angle to one another, so that four guide surfaces 13 are present, the adjacent ones of which are in each case aligned perpendicularly to one another. The guide portion thereby has a height H₁₁ and a width B₁₁, which are of equal size (H₁₁=B₁₁). The guide surfaces 13 do not end directly on one another in the cross section, the square cross section has chamfered corners 14 instead, which in each case lie between the adjacent guide surfaces. Alternatively, the chamfered corners 14 are formed as rounded corners.

The axial stop 12 has a cross section, which corresponds essentially to the shape of the cross section of the guide portion 11, but which is formed to be larger as a whole, in the present case, its width B₁₂ is in particular larger than its height H₁₂ (B₁₂>H₁₂). Moreover, its width B₁₂ is larger than the width B₁₁ and the height H₁₁ of the guide portion 11 (B₁₂>B₁₂, H₁₁). The axial stop 12 optionally also has a square cross section with chamfered corners. When viewed in the longitudinal extension, the axial stop 12 is formed to be shorter than the guide portion 11 (L₁₁>L₁₂) according to the present exemplary embodiment. Alternatively, the axial stop is formed to be of the same length or longer than the guide portion 11. In the present case, the guide portion 11 and the axial stop 12 are thereby aligned to one another in such a way that the guide surfaces 13 are aligned parallel to corresponding flat surfaces of the axial stop 12. The axial stop 12 can generally have any cross section, as long as the axial stop 12 has a cross section, which is larger than the cross section of the guide opening 4, so that it is ensured that the axial stop 12 can exert a force onto the carrier part 2 in the longitudinal displacement direction at least in some regions. The axial stop 12 is generally formed to be larger in the cross section than the guide portion 11 and also to be larger than the guide opening 4, so that the axial stop 12 can abut axially or on the front side, respectively, of the carrier part 2 or does abut in the rebounded state of the test probe 5, respectively. The larger the height H₁₂ and width B₁₂ of the axial stop 12, the larger the axial stop surface, which interacts with the carrier part 2. The wobbling centering of the test probe 5 improves with increasing stop surface 19, when said test probe is pushed by means of the spring element 10 into the rebounded state, in which the axial stop 12 abuts on the carrier part 2. The stop surface 19 of the axial stop 12 is thereby expediently formed perpendicularly to the longitudinal extension of the test probe 5, in order to ensure a plane-parallel alignment in the stop state, in the case of which the test probe 5 or the longitudinal axis thereof, respectively, in particular central longitudinal axis M or an eccentric longitudinal axis parallel to the central longitudinal axis, extends parallel to the longitudinal axis of the carrier part 2. In the case of non-parallel position of the stop surface 19 to the front surface of the carrier part 2, the axial stop 12 generates a tilting moment, which always forces the test probe 5 into the axially parallel alignment upon reaching the stop.

FIG. 4 shows a perspective longitudinal sectional illustration, which has an offset to the central longitudinal axis M of the test probe 5, so that the sectional plane does not run through the central longitudinal axis M, but lies radially offset thereto. The guide opening 4 has a cross section, which is at least essentially complementary to the cross section of the guide portion 11. The guide opening 4 thus likewise has a square cross section. Wherein the corners are not chamfered but rounded according to the present exemplary embodiment and in contrast to the cross section of the guide portion 11. The width and height of the square cross section is thereby only slightly larger than that of the guide portion 11, as also shown, for example, in FIG. 6, so that the guide portion 11 is displaceably mounted in the guide opening 4 with low wear. Due to the fact that each of the guide surfaces 13 is in each case assigned a guide counter surface 15 due to the square cross section of the guide opening 4, the test probe 5 can advantageously be displaced in the longitudinal direction or axially, respectively. Due to the size differences, it is attained that on the one hand, the housing 6 is safely guided in the guide opening 4 and, on the other hand, can be twisted or tilted by a limited angle of rotation about the central longitudinal axis M relative to the carrier part 2. A tilting thereby in particular takes place about an eccentric longitudinal axis of the test probe, which lies parallel to the central longitudinal axis. The smaller the size differences, the smaller the maximum angle of rotation. Independently of its size, the maximum angle of rotation is constant, however, independently of the sliding position of the housing 6 in the carrier part 2.

On its end facing the spring element 11, the guide opening 4 has a tapering in the form of a step 16, the inner diameter or inner cross section of which is smaller than the outer diameter or cross section of the housing 6 on the end of the guide portion 11, so that the guide portion 11 cannot be pushed farther than to the step 16 in the direction of the arrow A through the carrier part 2. However, before the guide portion 11 reaches the step 16 with its free, the axial stop 6 strikes against the carrier part 2. For this purpose, the longitudinal extension of the housing part from the free end of the guide portion 11 to the axial stop 6 (L₁₁+L₁₇) is formed to be smaller than the depth or length of the guide opening 4 to the step 16.

As can furthermore be seen well in FIG. 3, the housing 6 has a transfer portion 17 in the transfer from the guide portion 12 to the axial stop 6. Compared to the axial extension L₁₂ of the axial stop 12 and the axial extension L₁₁ or length, respectively, of the guide portion 11, the length L₁₇ of the transfer portion 17 is formed to be significantly shorter (L₁₇<<L₁₁, L₁₂). The housing 6 has a circular cross section in the transfer portion 17. The diameter of the circular shape is thereby chosen to be at most as large as the smallest inner width or diagonal in the cross section of the guide opening 4, so that the transfer portion 17 can be inserted completely into the guide opening 4. Due to the circular shape, the twistability of the housing 6 in the guide opening 4 is unchanged even when the transfer portion 17 is pushed into the guide opening 4, so that the circular shape does not obstruct a twisting of the housing 6 in the guide opening 4. The transfer portion 17, which is inserted into the guide opening 4, has the effect, however, that the test probe 5 can no longer be pivoted or can be pivoted less strongly in its longitudinal extension relative to the carrier part 2. The transfer portion 17 thus only limits a tumble movement of the test probe 5. The transfer portion 17 can also be referred to as wobbling centering in this respect.

Preferably, and as shown in the figures, the transfer portion 17 has a diameter, which is larger than height or width of the square cross section of the guide portion 11, so that the transfer portion 17 projects radially beyond guide surfaces 13 in some regions. Apart from that, the diameter of the transfer portion 17 is selected to be smaller than the largest diagonal of the cross section of the guide portion 11, so that the guide portion 11 projects beyond the transfer portion 17 in other regions—when viewed in the circumferential direction. The guide portion 11 projects beyond the transfer portion 17 in the radial direction in particular in the region of the chamfered corners 14. According to an alternative exemplary embodiment, not illustrated here, the guide portion 11 is continued all the way to the axial stop 6 in the region, in which the diameter of the transfer portion 17 is smaller than the cross section of the guide portion 11, so that the circular shape or transfer portion 17 of the circular shape, respectively, is visible and is effective in some regions only in the region of the guide surfaces 13.

To simplify the insertion of the transfer portion 17 into the guide opening 4, the transfer portion in each case has, in the region of each of the guide surfaces 13, a lead-in slope 18, which leads from the respective guide portion 13 in the direction of the outer diameter or diameter of the transfer portion 17, respectively. The lead-in slope 18 thus rises radially in the direction of the axial stop 12. The respective lead-in slope 18 thus obtains a surface in the shape of a segment of a circle. In response to the insertion of the transfer portion 17 into the guide opening 4, the lead-in slopes 18 effect a wobbling centration of the test probe 5 relative to the carrier part 2, by means of which the wobbling of the test probe 5 is reduced and the test probe is thus centered with respect to its tumble movement. The transfer portion preferably has a length of this type, so that the test probe 5 is safely aligned and centered in response to the rebounding, and so that the test probe can carry out a tumble movement quickly in response to the spring deflection or after a short spring travel, respectively, after a first contact-making with the contact partner. The transfer portion 17 thus has, for example, an axial extension or length of 0.05 mm to 0.5 mm. In addition, the initial position of the test probe 5 is supported in the completely rebounded state by means of the axial stop 12, which has a stop surface 19, which is aligned perpendicularly to the longitudinal extension of the probe 5 and which abuts flat on the carrier part 2 in the rebounded state, as has already been described above.

Due to the advantageous formation of the test probe device 1, it is thus attained that the test probe 5 can be twisted in the bearing part 2 up to a maximum angle of twist about its central longitudinal axis M, and can moreover be pivoted or can tumble, respectively, with its longitudinal axis relative to the longitudinal axis of the carrier part 2. In the rebounded initial position, the tumble movement is caught with the help of the lead-in slope 18 and the transfer portion 17, while the rotational limitation remains constant over the entire longitudinal displacement of the test probe 5.

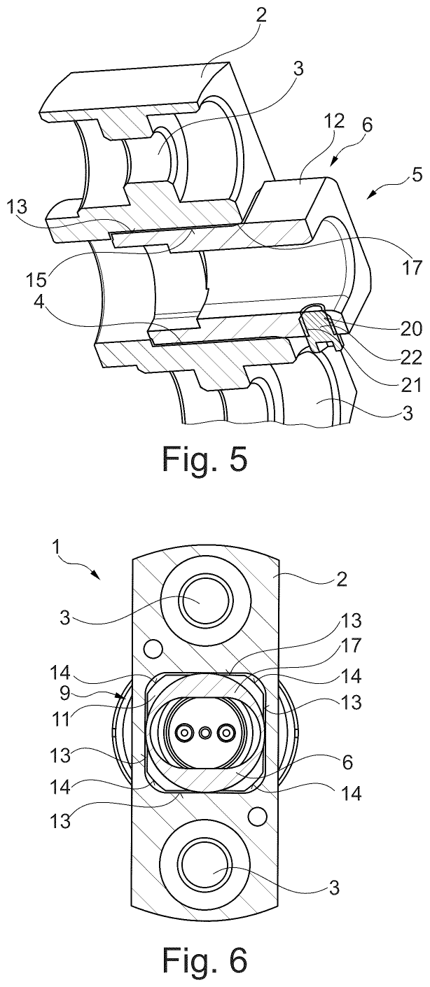

FIG. 5 shows a perspective illustration of the housing part of the housing 6 having the guide portion 11 in the bearing part 2 in the rebounded state. It can be seen here in each case that the axial stop 6 projects beyond the guide opening 4 and thus strikes the bearing part 2 with the axial stop surface 19, which prevents a further rebounding. Moreover, FIG. 5 shows that the transfer portion 17 lies in the guide opening 4.

With regard to this, FIG. 6 moreover shows in a perspective cross sectional illustration, at which the sectional plane lies in the region of the transfer portion 17, that the rotatability of the test probe 5 in the guide opening 4 is not adversely effected due to the circular shape, the diameter of which corresponds at most to the smallest diagonal of the square cross section of the guide opening 4. The maximum angle of rotation is thus defined solely by the guide surfaces 18 or the cross sections of guide portion 11 and guide opening 4, respectively.

In the region of the axial stop 12, the test probe device 1 optionally has a cross hole 20 in the housing, which is aligned radially. The cross hole 20 in particular has a thread 21, into which a holding screw 22, for example grub screw, as shown in an exemplary manner in FIG. 5, can be screwed or is screwed, in order to clamp connection cables, which are inserted into the housing 6 at the end of the housing 6 facing away from the contact section 9 in order to make electrical contact with the contact elements 8, in order to ensure a strain relief for the contact points.

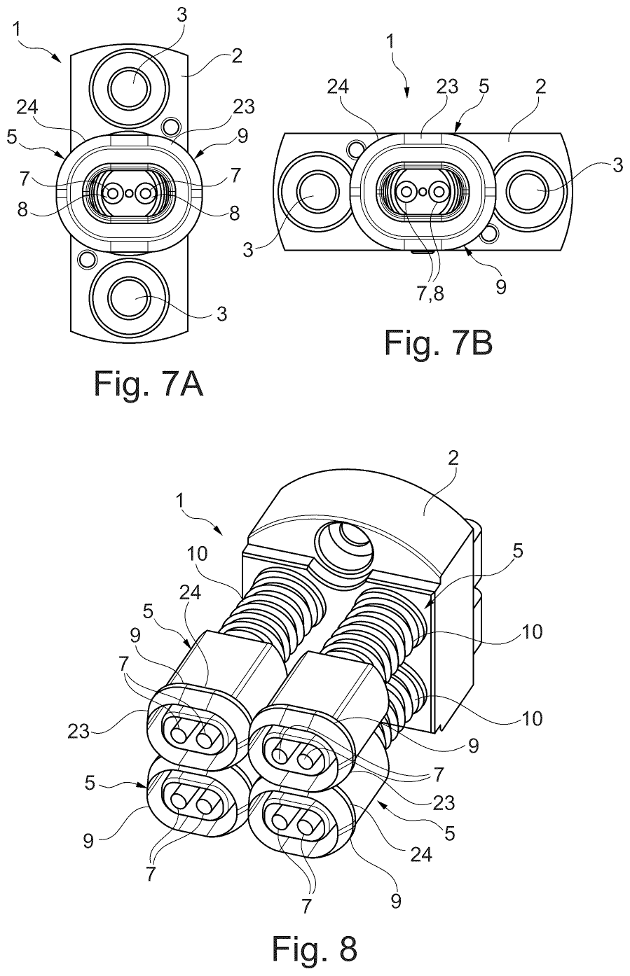

The advantageous formation of the guide section and of the guide opening with square cross section in each case makes it possible to insert the test probe 5 into the carrier part 2 in different rotational positions, in each case offset by 90 degrees. For this purpose, FIGS. 7A and B show different assembly positions for the test probe 5 on the carrier part 2, which lie so as to be twisted by 90 degrees to one another. A simple adaptation of the test probe device 1 to different contact partners or boundary conditions is thus ensured. The contact portion 9 is preferably essential for the dimensioning of the bearing part 2. It is thus preferably provided that the width of the bearing part 2, as shown in FIGS. 7A and B, is not wider than the width of the contact end 9.

FIG. 8 shows a further exemplary embodiment of the test probe device 1, that differs from the preceding exemplary embodiment in that several guide openings 4 are formed in the bearing part 2, wherein a test probe 5 is inserted into each of the guide openings 4. The test probes 5 and the guide openings 4 are formed as described above. A plurality of test probes 5 can thus be used in a bearing part 2.

The respective contact portion 9 of the test probe 5 or of the housing 6, respectively, advantageously moreover has a lead-in slope 23 in particular on its outer side, in order to effect a centering of the test probe 5 to the contact partner in response to a contact-making process. The lead-in slope 23 effects in particular a wide or long and gentle insertion region on the contact partner as well as a virtually play-free centering on the inner region or on the inner side of the contact partner, respectively. The external geometry as well as the internal geometry of the contact portion 9 simultaneously allow an axial tilt (wobbling) of the test probe 5, without the components mutually canting. It is provided for this purpose that the lead-in slope 23 ends in an elevation 24, the cross section of which is larger than the jacket region of the housing 6 facing away from the free end of the contact portion 9. A narrow or line-shaped contact region between the contact portion 9 and the inner side of the contact partner is ensured by means of the elevation 24, so that a canting or jamming of the test probe 5 in the contact partner is reliably prevented even in response to a tumble movement of the test probe 5. The lead-in slope 23 is preferably coordinated with the spring force of the spring element 10 in such a way that the spring deflection and wobbling of the test probe 5 begins only after safe contact-making with the contact partner, without damage occurring on the contact partner.

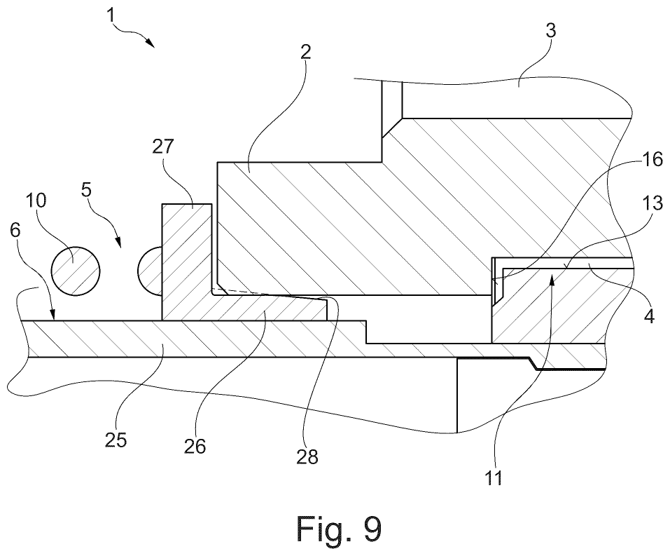

FIG. 9 shows the test probe device 1 in the region of the carrier parts 2 on the side facing away from the axial stop 12 in an enlarged longitudinal sectional illustration. In continuation of the guide portion 11, the housing 6 has a jacket portion 25, which is guided radially in a play-free manner in the carrier part 2. For this purpose, a bearing ring 26 is arranged in the present case between the carrier part 2 and the jacket portion 25 in the region of the portion of the guide opening 4, which has a tapered cross section, which forms the step 16. However, the bearing ring 26 can also be inserted in a guide opening with continuously constant cross section. The tapered cross section of the step 16 is preferably formed in a circular manner, so that it does not have any influence on a possible rotation of the test probe 5 in the guide opening 4. The bearing ring 26 is formed in an elastically deformable manner and is held so as to be tensioned radially between carrier part 2 and jacket wall 25 or housing 6, respectively, so that it is elastically deformed. For example, the outer diameter of the bearing ring 26 is, for this purpose, slightly larger than the inner diameter of the guide opening 4 of the carrier part 2 in the region of the step 16 at least in some sections and/or its inner diameter is slightly smaller than the jacket portion 25 of the housing 6, so that, in the assembled position, as illustrated in FIG. 9, the bearing ring 26 deforms radially elastically and is thus held so as to be pretensioned or tensioned, respectively. The bearing ring 26 is thereby formed as sliding ring, so that the housing 6 is axially displaceably or slidingly mounted, respectively, with the jacket portion 25 in the bearing ring, in order to provide for the spring deflection and rebounding of the test probe 5.

The bearing ring 26 preferably has a radially projecting bearing ring stop 27, which limits the maximum axial penetration depth of the bearing ring 26 into the carrier part 2 and which lies between the carrier part 2 and the spring element 10 in such a way that the spring element axially supports itself on the bearing ring stop 27. The bearing ring stop 27 is preferably formed in one piece with the bearing ring 26. Particularly preferably, the bearing ring 26 has a lead-in slope 28, which forms an outer diameter of the bearing ring 26, which decreases in the insertion direction. For this purpose, the bearing rings 26 is in particular formed to be conical at least on the jacket outer wall. In the undeformed state of the bearing ring 26, thus, for example, prior to the assembly, the conical shape of the bearing ring 26 or the lead-in slope 28, respectively, thereby preferably extends from the free end, which is to be inserted into the carrier part 2, all the way to the bearing ring stop 27, as displayed in FIG. 9 by means of a dashed line. The bearing ring 26 is pushed axially into the guide opening 4 or into the tapered portion of the guide opening 4, respectively,, by means of the spring element 10 or by means of the pretensioning force provided by the spring element 10, respectively, so that the bearing ring 26 is thus elastically deformed or pressed, respectively, with increasing insertion depth. A plastic deformation of the bearing ring 26 can optionally also take place thereby.

Due to the deformation of the bearing ring 26, it is attained that with the jacket portion 25, the test probe 5 is guided in a play-free manner in the carrier part 2 in the region of the step 16. A tumble bearing or a bearing point, respectively, by means of which a tumble axis for the test probe 5 is defined, is thus offered to the test probe 5 in the region of the step 16, wherein the tumble axis is aligned transversely to the longitudinal extension of the test probe 5 or longitudinal axis of the guide opening 4, respectively. Together with the transfer portion 17 and the axial stop 12, the tumble movement of the test probe 5 is optimized by means of the bearing ring 26 by means of the improved linear guidance relative to the carrier part 2. With increasing distance of bearing ring 26 from the open end of the guide opening 4, which faces the axial stop 12, the guidance of the test probe 5 becomes more precise and the permitted wobbling angle becomes smaller. Depending on the application, a preferred ratio of distance, cross sectional shape and size of the axial stop 12 as well as of the guide portion 11 and of the guide opening 4 is to thus be selected, in order to provide for smaller or larger tumble movements of the test probe 5 relative to the carrier part 2.

It is moreover ensured by means of the spring force application of the bearing ring 26 and of the lead-in slope 28 thereof that the bearing ring is automatically moved farther into the carrier part 4 in case of signs of wear, in order to maintain the play-free mounting.

1. A test probe device for making electrical contact with an multi-pole contact partner, with a carrier part, which has at least one guide opening, and with at least one test probe, which is longitudinally displaceably mounted in the guide opening, wherein the test probe has a cylindrical housing in which one or more pin-shaped contact elements are arranged, each of which have a contact end for making contact with the contact partner, wherein the housing has a guide portion longitudinally displaceably mounted in the guide opening and a contact portion spaced apart therefrom, and wherein the contact ends-are assigned to the contact portion, wherein a spring element is pretensioned between the contact portion and the carrier part and, adjoining the guide portion at the housing, on the side of the carrier part facing away from the spring element, an axial stop is formed, which interacts with the carrier part against the spring force of the spring element, wherein a maximum rotational and/or tilting angle of the test probe is limited about a longitudinal axis relative to the carrier part-by the guide opening and the guide portion, for the purpose of which the guide opening and the guide portion in each case have a polygonal cross section with at least one straight line, and wherein guide portion and guide opening are formed in such a way that the test probe-can tumble in at least one sliding position relative to the carrier part, wherein a transfer portion is formed between the guide portion and the axial stop, that the transfer portion has a circular cross section, the diameter of which is at most as large as the smallest inner width of the cross section of the guide opening on the one hand and smaller than the largest diagonal and larger than the smallest inner width of the cross section of the guide portion on the other hand, so that the transfer portion, when viewed over its circumference, radially projects beyond the guide portion only in some regions.

2. The test probe device according to claim 1, wherein the transfer portion has a lead-in slope in at least one region projecting beyond the guide portion.

3. The test probe device according to claim 1, wherein the lead-in slope leads from the guide portion so as to rise into the transfer portion.

4. The test probe device according to claim 1, wherein the guide portion has a square cross section.

5. The test probe device according to claim 1, wherein the guide opening has a square cross section.

6. The test probe device according to claim 1, wherein the guide portion has corners, which are chamfered in the cross section.

7. The test probe device according to claim 1, wherein the guide opening has corners, which are rounded in the cross section.

8. The test probe device according to claim 1, wherein the maximum angle of rotation is limited independently of a longitudinal displacement of the test probe in the carrier part.

9. The test probe device according to claim 1, wherein the guide opening has, on its end facing away from the axial stop, a step, which tapers the cross section, and that the total length of guide portion and transfer portion is smaller than the distance of the step from the free end of the guide opening facing the axial stop.

10. The test probe device according to claim 1, wherein the housing has, in the region of the axial stop, a cross hole with a thread for a holding screw, by means of which connection cables can be fastened in the housing.

11. The test probe device according to claim 1, wherein the contact portion of the housing has, on its free end, at least one lead-in slope for centering on the contact partner.

12. The test probe device according to claim 1, wherein the contact end of the respective contact element lies completely within the housing, recessed from the free front side of the contact portion.

13. The test probe device according to claim 1, wherein the carrier part-has one or more fastening openings spaced apart from the guide opening.

14. The test probe device according to, wherein the carrier part has several guide openings, in which a test probe is assembled or can be assembled in each case.

15. The test probe device according to, wherein the carrier part has a width, which is smaller than or equal to the width of the contact portion.

16. The test probe device according to claim 1, wherein the housing has, between the guide portion and the contact potion, a jacket portion, which surrounds the one or the several contact elements and which is guided radially in the carrier part, in particular in a tapered portion of the guide opening.

17. The test probe device according to claim 16, characterized in that wherein for guidance purposes a bearing ring is present, which is elastically and/or plastically deformable at least in some regions and which is held in a radially tensioned manner at least in some portions between the jacket portion and the carrier part.

18. The test probe device according to claim 16, wherein the bearing ring has a lead-in slope for the carrier part and is formed conically for this purpose.

19. The test probe device according to claim 17, wherein the bearing ring has a radially projecting bearing ring stop, which is held axially between the spring element and the carrier part.
